(19) United States
(12) Patent Application Publication
(10) Pub. No.: US 2012/0264243 A1
(43) Pub. Date: Oct. 18, 2012

(54) FLEXIBLE LIQUID CRYSTAL DISPLAY PANEL AND METHOD FOR MANUFACTURING THE SAME

(75) Inventors: Wei-Hung KUO, Hsin-Chu City (TW); Tun-Chun Yang, Hsin-Chu City (TW); Seok-Lyul Lee, Hsin-Chu City (TW); Wei-Ming Huang, Hsin-Chu City (TW)

(73) Assignee: AU OPTRONICS CORP., Hsin-Chu (TW)

(21) Appl. No.: 13/537,255

(22) Filed: Jun. 29, 2012

Related U.S. Application Data
(63) Continuation of application No. 12/318,548, filed on Dec. 31, 2008.

(30) Foreign Application Priority Data
Sep. 15, 2008 (TW) 97135390

(51) Int. Cl. H01L 33/08

(52) U.S. Cl. 438/30; 257/E33.012

(57) ABSTRACT

A flexible liquid crystal display panel and method for manufacturing the same are provided. The flexible liquid crystal display panel includes a rigid substrate, a flexible substrate and a liquid crystal layer disposed therebetween.

This is a continuation application of co-pending U.S. patent application Ser. No. 12/318,548, filed Dec. 31, 2008, and for which priority is claimed under 35 U.S.C. §120; and this application claims the benefit of Taiwan Patent Application Serial No. 97135390, filed Sep. 15, 2008, the contents of which are incorporated herein by reference.

### BACKGROUND OF THE INVENTION

1. Field of the Invention

The present invention generally relates to a flexible liquid crystal display panel and a method for manufacturing the same, and especially relates to a color-filter-on-array (COA) flexible liquid crystal display panel and a method for manufacturing the same.

2. Description of Related Art

Flexibility of flat displays depends upon the materials of the substrate.

For example, the flat display is not of flexibility if the substrate it used is solid, such as glass. In contrast, the flat display is of good flexibility if the substrate it used is flexible, such as plastic.

Although the technology of forming thin film transistors on a solid substrate is growing to be mature, method for forming thin film transistors on a flexible substrate still needs to be improved. Conventionally, a flexible substrate has to be stuck onto a solid substrate before performing a series of films forming steps when forming thin film transistors on a flexible substrate. Because of extreme thermal expansion coefficient mis-match between the flexible substrate and the solid substrate, the flexible substrate may bend under high operation temperature when applying different films forming steps on the flexible substrate, lithographic process and etching process under high temperature. It should be noticed that serious mis-alignment between films may occur to result in process failure if the films forming process is performed on a bent flexible substrate. Thermal shaping plastic substrates having high transparency have poor thermal durability, while that having better thermal durability have poor transparency.

Therefore, process capability of the flexible array substrate is difficult to increase.

### SUMMARY OF THE INVENTION

Accordingly, the present invention is directed to a flexible liquid crystal display panel which can be manufactured under high temperature.

An objective of the present invention is to provide a flexible liquid crystal display panel which is a reflective COA flexible liquid crystal display panel having better flexibility.

An objective of the present invention is to provide a flexible liquid crystal display panel which is a transmissive COA flexible liquid crystal display panel having better flexibility.

An objective of the present invention is to provide a method for manufacturing a flexible liquid crystal display panel under high temperature.

In accordance with the above objectives and other objectives, the present invention provides a method for manufacturing a flexible liquid crystal display panel, comprising forming a solid substrate which includes a solid base having a thickness of about 100 micrometer to 700 micrometer, forming a flexible substrate having a flexible base, and forming a liquid crystal layer between the solid substrate and the flexible substrate.

In accordance with the above objectives and other objectives, the present invention provides a method for manufacturing a flexible liquid crystal display panel, comprising forming a first flexible substrate, forming a second flexible substrate, and forming a liquid crystal layer between the first flexible substrate and the second flexible substrate. The step of forming the first flexible substrate comprises providing a first carrier, and forming a first flexible base on the first carrier. The step of forming the second flexible substrate comprises providing a second carrier, forming a second flexible base on the second carrier, and forming an active array on the second flexible base.

In accordance with the above objectives and other objectives, the present invention provides a flexible liquid crystal display panel. The flexible liquid crystal display panel comprises a solid substrate, a flexible substrate, and a liquid crystal layer disposed between the solid substrate and the flexible substrate. The solid substrate comprises a solid base, and a COA disposed on the solid substrate.

In accordance with the above objectives and other objectives, the present invention provides a flexible liquid crystal display panel. The flexible liquid crystal display panel comprises a first flexible substrate, a second flexible substrate, and a liquid crystal layer disposed between the first flexible substrate and the second flexible substrate. The first flexible substrate comprises a first flexible base. The second flexible substrate comprises a second flexible base, an active array disposed on the second flexible base, an insulating material layer disposed, having bumps, on the active array, a reflective layer disposed on the bumps, and a color filter layer disposed on the reflective layer.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 3B show a method for manufacturing a reflective COA flexible liquid crystal display panel according to the first embodiment of the present invention;

FIGS. 4A to 6B show a method for manufacturing a transmissive COA flexible liquid crystal display panel according to the second embodiment of the present invention; and

FIGS. 7A to 9B show a method for manufacturing a reflective COA flexible liquid crystal display panel according to the third embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

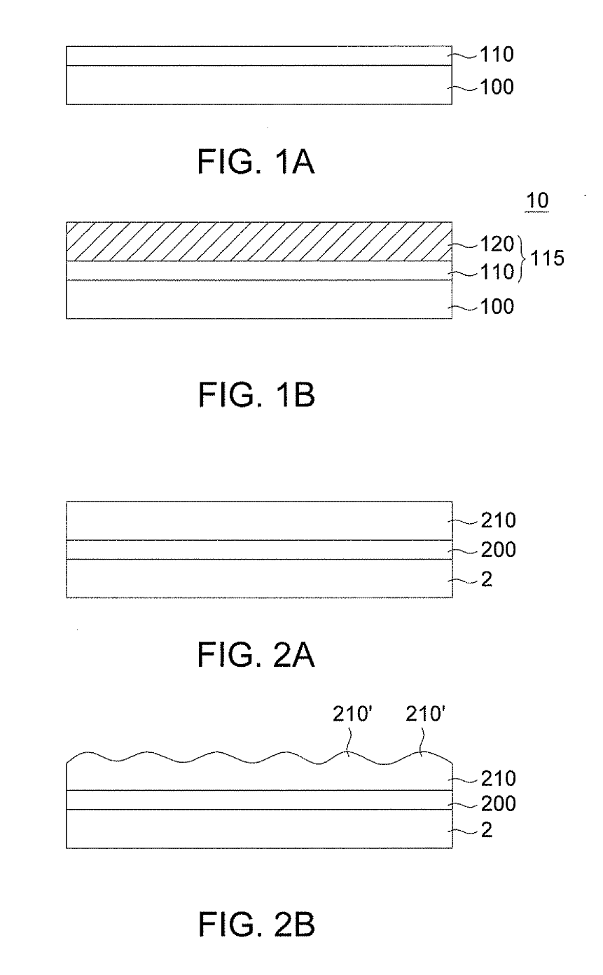

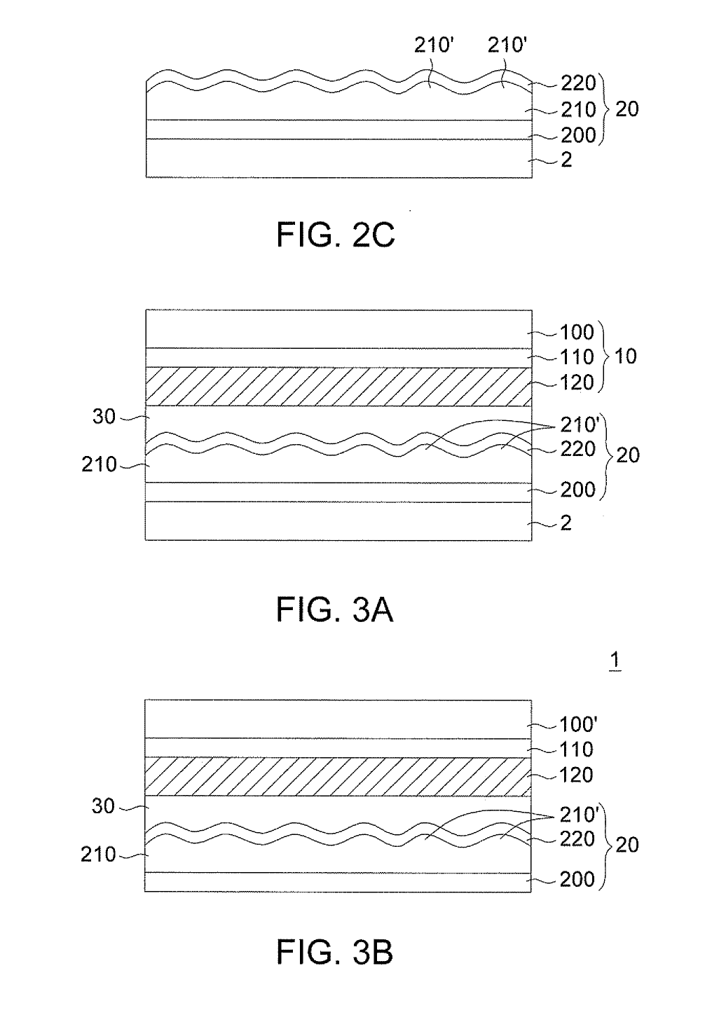

FIGS. 1A to 3B show the method for manufacturing the reflective color-filter-on-array (COA) flexible liquid crystal display panel according to the first embodiment of the present invention. FIGS. 1A to 1B show the method for manufacturing the solid substrate according to the present embodiment. FIGS. 2A to 2C show the method for manufacturing the flexible substrate according to the present embodiment.

FIGS. 1A to 1B show the method for manufacturing the solid substrate. As shown in FIGS. 1A and 1B, first, provide solid base 100. The solid base 100 has thickness of about 100 micrometer to about 700 micrometer. The solid base 100 is comprised of glass or quartz. Next, under the process temperature of 220° C. to about 700° C., form color-filter-on-array 115 on the solid base 100. The step of forming the color-filter-on-array 115 comprises forming active array 110 on the solid base 100, as shown in FIG. 1A, and then forming color filter layer 120 on the active array 110 to form the color-filter-on-array 115 as shown in FIG. 1B. Therefore, the solid substrate 10 is formed.

FIGS. 2A to 2C show the method for forming a flexible substrate. As shown in the FIGS. 2A to 2C, provide carrier 2 and form flexible base 200 on the carrier 2. The flexible base 200 is comprised of plastic, which may be transparent, foe example, Polycarbonate (PC), Polyphenylene Sulfide (PES), polyethylene 2,6-naphthalate (PEN) or Polyimide (PI). The flexible base 200 has a thickness of about 50 micrometer to about 200 micrometer. Next, under the process temperature of about 20° C. to about 350° C., preferably, under about 20° C. to 150° C., form insulating material layer 210 on the flexible base 200. The insulating material layer 210 is comprised of organic. Then, as shown in FIG. 2B, pattern the insulating material layer 210 to form bumps 210′ thereon. Finally, as shown in FIG. 2C, form reflective layer 220 on the bumps 210′, that is to say, form reflective layer 220 on the top surface of the insulating material layer 210 which has bumps 210′. The reflective layer 220 is comprised of metal, such as molybdenum (Mo), aluminium (Al) or the combination thereof, for example. As a result, the reflective layer 220 has uneven surface to reflect the light, such as environmental light for example, entering and passing through the solid base 10 in order to achieve the goal of making a reflective display panel. Therefore, solid substrate 20 is formed.

Then, refer to FIGS. 3A to 3B. As shown in FIG. 3A, form liquid crystal layer 30 between the solid substrate 10 and the flexible substrate 20. The step of forming the liquid crystal layer 30 between the solid substrate 10 and the flexible substrate 20 comprises applying one drop fill process (ODF) or vacuum injection process. The solid substrate 10 and the flexible substrate 20 are assembled to connect with each other. Then, as shown in FIG. 3B, thin the solid base 100 to make the solid base 100′ have a thickness of about 100 micrometer to about 200 micrometer. The step of thinning the solid base 100 comprises etching or polishing. Remove the carrier 2 to isolate the flexible substrate 20 from the carrier 2. The sequence order of the steps of thinning the solid base 100 and the step of removing the carrier 2 is not limited, which may be proceed simultaneously, the thinning step before the removing step, or the thinning step after the removing step.

Therefore, reflective COA flexible liquid crystal display panel 1 according to the first embodiment of the present invention is manufactured. In the present embodiment, material of flexible base 200 may be replaced to thin metal film having flexibility, such as stainless steel having a thickness of about 50 micrometer to about 200 micrometer, for example, which can achieve the same goal above as well.

### Second Embodiment

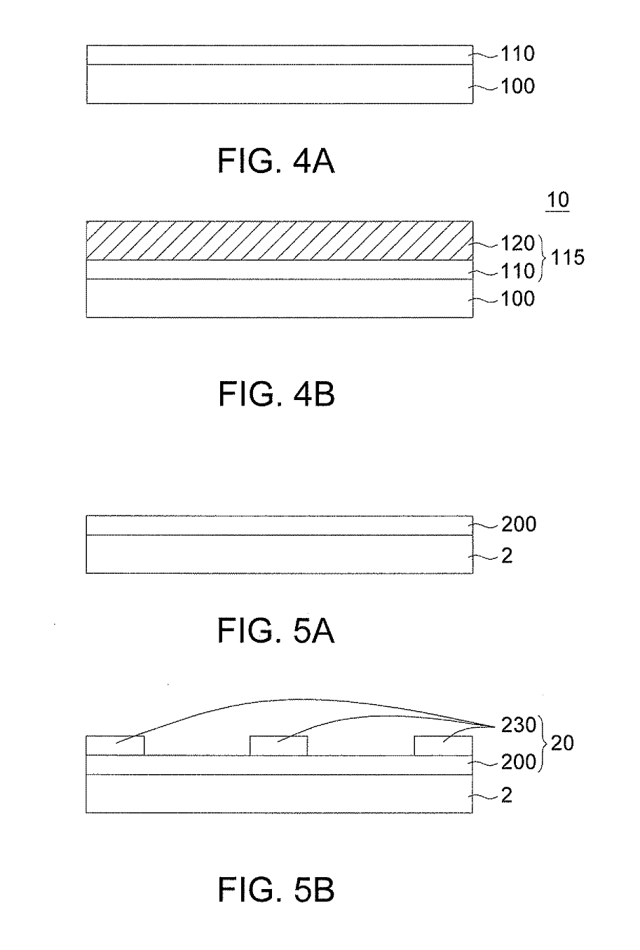

FIGS. 4A to 6B show a method for manufacturing a transmissive COA flexible liquid crystal display panel according to the second embodiment of the present invention. FIGS. 4A to 4B show the method for forming the solid substrate according to the present embodiment. FIGS. 5A to 5B show the method for manufacturing the flexible substrate according to the present embodiment of the present invention.

FIGS. 4A to 4B show a method for forming a solid substrate. As shown in FIGS. 4A and 4B, provide solid base 100 having a thickness of about 100 micrometer to about 700 micrometer, and comprised of glass or quartz, for example. Next, under the process temperature of 220° C. to about 700° C., form color-filter-on-array 115 on the solid base 100. The step of forming the color-filter-on-array 115 comprises forming active array 110 on the solid base 100, as shown in FIG. 4A, and then forming color filter layer 120 on the active array 110 to form the color-filter-on-array 115 as shown in FIG. 4B. Therefore, the solid substrate 10 is formed.

FIGS. 5A to 5B show the method for forming a flexible substrate. As shown in the FIGS. 5A to 5B, provide carrier 2 and form flexible base 200 on the carrier 2. The flexible base 200 is comprised of plastic, which may be transparent, foe example, Polycarbonate (PC) or Polyphenylene Sulfide (PES).

The flexible base 200 has a thickness of about 50 micrometer to about 200 micrometer. Next, under the process temperature of about 20° C. to 350° C., preferably, under about 20° C. to 200° C., as shown in FIG. 5B, form shielding matrix 230 on the flexible base 200. Shielding matrix 230 is comprised of black carbon, metal, resin or dark organic materials, etc, for example. The step of forming the shielding matrix 230 comprises completely forming shielding material (not shown) on the flexible base 200, and then patterning the shielding material to form the shielding matrix 230 by etching process or laser ablation process. Therefore, flexible substrate 20 is formed.

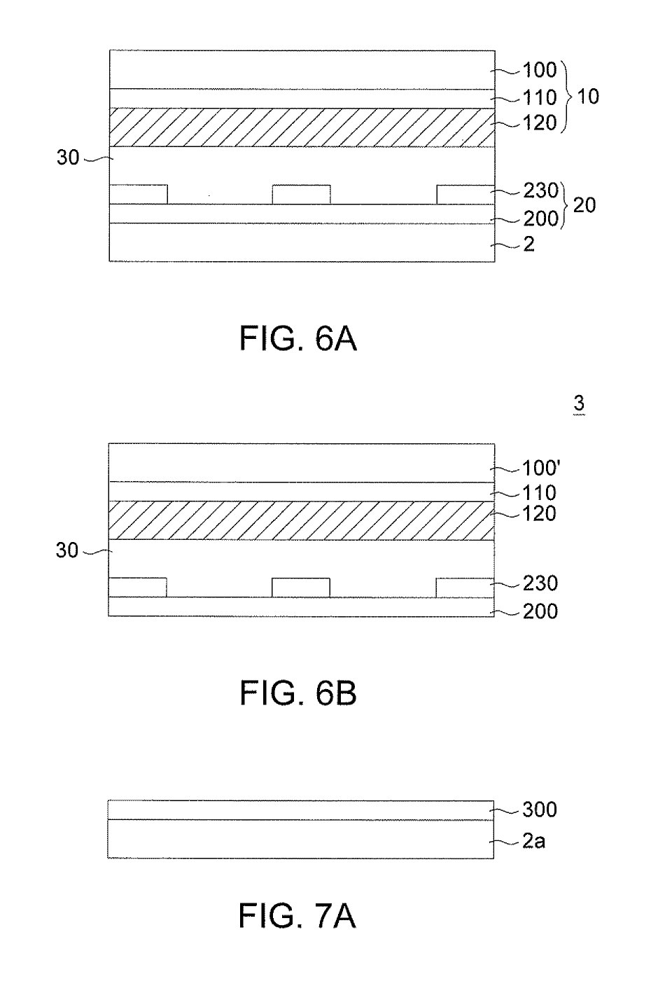

Then, refer to FIGS. 6A to 6B. As shown in FIG. 6A, form liquid crystal layer 30 between the solid substrate 10 and the flexible substrate 20. The step of forming the liquid crystal layer 30 between the solid substrate 10 and the flexible substrate 20 comprises applying one drop fill process (ODF) or vacuum injection process. The solid substrate 10 and the flexible substrate 20 are assembled to connect with each other. Then, as shown in FIG. 6B, thin the solid base 100 to make the solid base 100′ have a thickness of about 100 micrometer to about 200 micrometer. The step of thinning the solid base 100 comprises etching or polishing. Remove the carrier 2 to isolate the flexible substrate 20 from the carrier 2. The sequence order of the steps of thinning the solid base 100 and the step of removing the carrier 2 is not limited, which may be proceed simultaneously, the thinning step before the removing step, or thinning step after the removing step.

Therefore, transmissive COA flexible liquid crystal display panel 3 according to the second embodiment of the present invention is manufactured.

### Third Embodiment

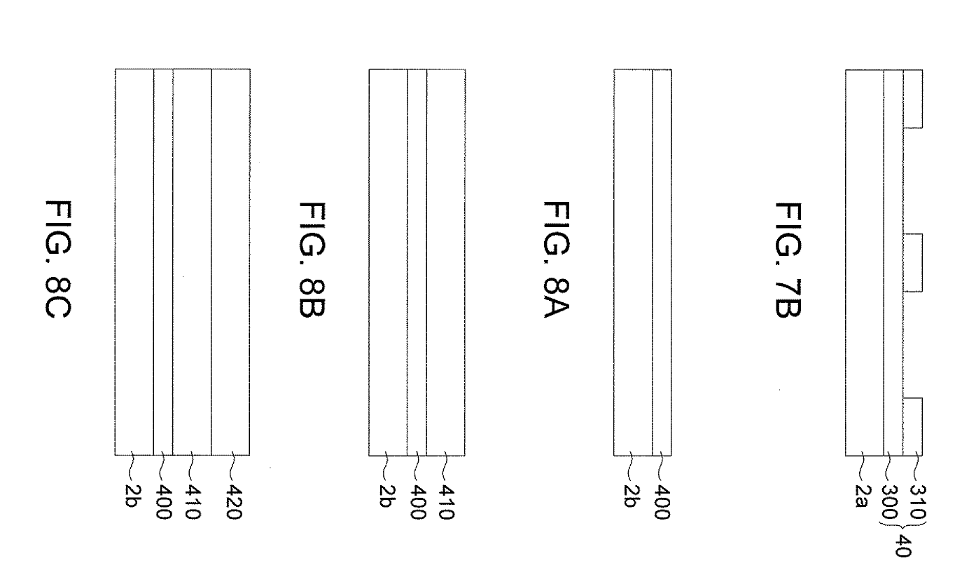

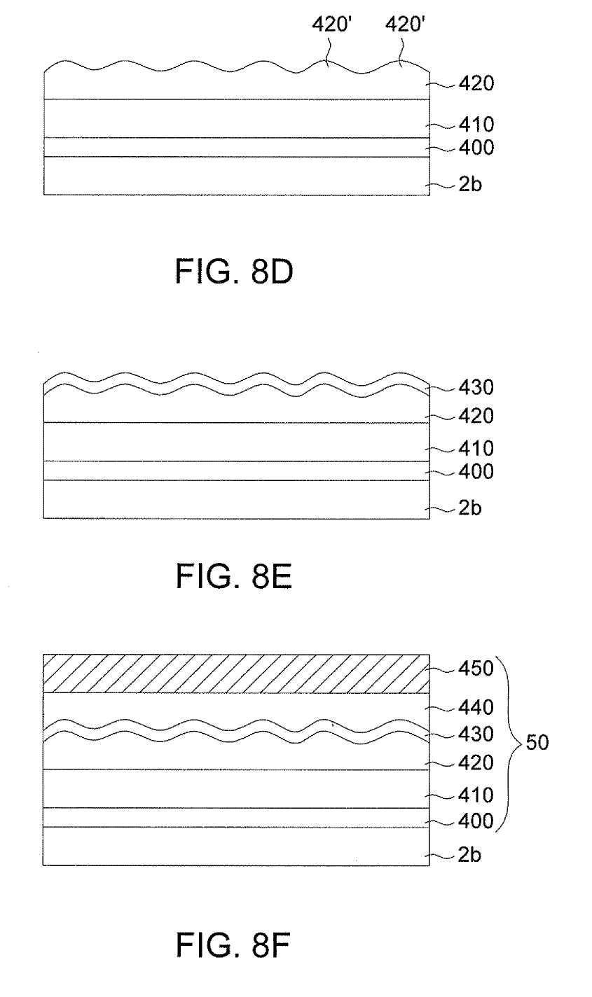

FIGS. 7A to 9B show the method for manufacturing the reflective color-filter-on-array (COA) flexible liquid crystal display panel according to the third embodiment of the present invention. FIGS. 7A to 7B show the method for manufacturing the first flexible substrate according to the present embodiment. FIGS. 8A to 8F show the method for manufacturing the second flexible substrate according to the present embodiment.

FIGS. 7A to 7B show the method for manufacturing the first flexible substrate. As shown in FIGS. 7A and 7B, provide first carrier 2a and form the first flexible base 300 on the first carrier 2a under the process temperature of about 20° C. to about 200° C. The first flexible base 300 is comprised of plastic, which may be transparent, foe example, Polycarbonate (PC) or Polyphenylene Sulfide (PES). Next, as shown in FIG. 7B, selectively form shielding matrix 310 on the first flexible base 300. Shielding matrix 310 is comprised of black carbon, metal, resin or dark organic materials, etc, for example. The step of forming the shielding matrix 310 comprises completely forming shielding material (not shown) on the first flexible base 300, and then patterning the shielding material to form the shielding matrix 310 by etching process or laser ablation process. Therefore, first flexible substrate 40 is formed.

Next, refer FIGS. 8A to 8F. FIGS. 8A to 8F show the method for forming the second flexible substrate. As shown in FIGS. 8A to 8F, provide second carrier 2b and form the second flexible base 400 on the second carrier 2b. The second flexible base 400 is comprised of plastic, which may be transparent, foe example, polyethylene 2,6-naphthalate (PEN) or Polyimide (PI). However, the second flexible base 400 may be comprised metal instead, such as stainless steel having a thickness of about 50 micrometer to about 200 micrometer. Then, as shown in FIG. 8B, form active array 410 on the second flexible base 400 under the process temperature of about 20° C. to about 350° C. In the step, the thermal durability of the second flexible base 400 comprised of the above mentioned metal may be better than that of the second flexible base 400 comprised of plastic. Next, as shown in FIG. 8C, form insulating material layer 420 on the active array 410. The insulating material layer 420 is comprised of organic. Pattern the insulating material layer 420 to form a plurality of bumps 420′ thereon. As shown in FIG. 8E, form reflective layer 430 on the top surface of the insulating material layer 420 which has bumps 410′. The reflective layer 430 is comprised of metal, such as molybdenum (Mo), aluminium (Al) or the combination thereof, for example. As a result, the reflective layer 430 has uneven surface to reflect the light, such as environmental light for example, entering and passing through the first flexible substrate 40 in order to achieve the goal of making a reflective display panel.

Then, as shown in FIG. 8F, form color filter layer 450 on the reflective layer 430. Optionally, before form the color filter 450 on the reflective layer 430, form passivation layer 440 on the reflective layer 430. That is to say, from passivation layer 440 on the reflective layer 430, and then, form the color filter 450 on the passivation layer 440. The passivation layer 440 is comprised of organic, for example. As a result, the second flexible substrate 50 is formed.

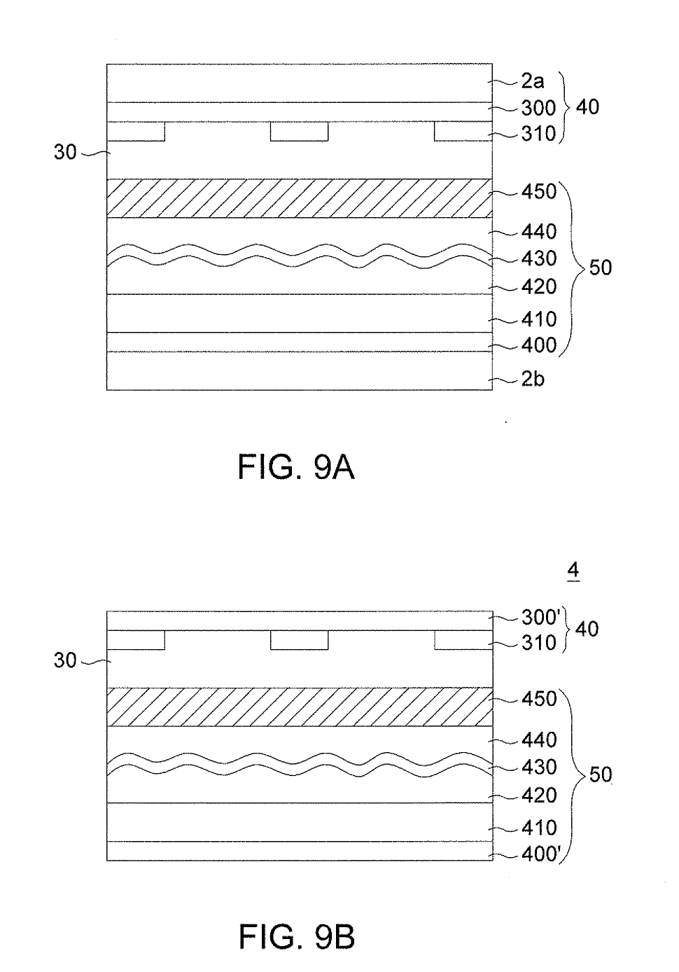

Then, refer to FIGS. 9A to 9B. As shown in FIG. 9A, form liquid crystal layer 30 between the first flexible substrate 40 and the second flexible substrate 50. The step of forming the liquid crystal layer 30 between the first flexible substrate 40 and the second flexible substrate 50 comprises applying one drop fill process (ODF) or vacuum injection process. The first flexible substrate 40 and the second flexible substrate 50 are assembled to connect with each other.

Then, as shown in FIG. 9B, thin the second flexible base 400. The step of thinning the second flexible base 400 comprises etching or polishing. Similarly, the first flexible base 300 may be optionally thinned in the same way as mentioned above. Remove the first carrier 2a and the second carrier 2b so that the first flexible substrate 40 and the second flexible substrate 50 can be isolated from the first carrier 2a and the second carrier 2b, respectively. However, the sequence order of the steps of thinning base(s) and removing the carrier(s) is not limited, which may be proceed simultaneously, the thinning step(s) before the removing step(s), or the thinning step(s) after the removing step(s).

Therefore, reflective COA flexible liquid crystal display panel 4 according to the third embodiment of the present invention is manufactured.

In the embodiments of the present invention, the active array comprises thin film transistor array, for example. The color filter layer comprises color filter array composed of red, green, blue or other color filter layers.

Because the process temperature of at least one of the embodiments of the present invention may be under high temperature and all the steps can be proceeded continuously or proceeded in the same or similar process conditions, or at the single or few operation stages, the process time cost can be saved efficiently.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a flexible liquid crystal display panel, comprising:
forming a solid substrate, wherein the solid substrate comprises a solid base;
forming a flexible substrate, wherein the flexible substrate comprises a flexible base;
forming a liquid crystal layer between the solid substrate and the flexible substrate; and
thinning the solid base after the step of forming the liquid crystal layer between the solid substrate and the flexible substrate.

2. The method according to claim 1, wherein the thickness of the solid base is about 100 micrometer to about 700 micrometer.

3. The method according to claim 1, wherein the thickness of the solid base is about 100 micrometer to about 200 micrometer.

4. The method according to claim 1, wherein the flexible base has a thickness of about 50 micrometer to about 200 micrometer.

5. The method according to claim 1, wherein the step of forming the solid substrate comprises:
providing the solid base; and
forming a color-filter-on-array (COA) on the solid base.

6. The method according to claim 5, wherein the step of forming the flexible substrate comprises:
providing a carrier;
forming the flexible base on the carrier;
forming an insulating material layer on the flexible base;
patterning the insulating material layer to form a plurality of bumps thereon; and
forming a reflective layer on the plurality of bumps.

7. The method according to claim 6, further comprising:
removing the carrier.

8. The method according to claim 6, wherein the step of forming the solid substrate is under a temperature of about 220° C. to about 700° C., and the step of forming the flexible substrate is under a temperature of about 20° C. to about 350° C.

9. The method according to claim 6, wherein the flexible base is comprised of Polycarbonate (PC), Polyphenylene Sulfide (PES), polyethylene 2,6-naphthalate (PEN) or Polyimide (PI).

10. The method according to claim 5, wherein the step of forming the flexible substrate comprises:
providing a carrier; and
forming the flexible base on the carrier, wherein the flexible base is transparent.

11. The method according to claim 10, wherein the flexible base is comprised of Polycarbonate (PC) or Polyphenylene Sulfide (PES).

12. The method according to claim 10, further comprising:
removing the carrier.

13. The method according to claim 10, wherein the step of forming the solid substrate is under a temperature of about 220° C. to about 700° C., and the step of forming the flexible substrate is under a temperature of about 20° C. to about 350° C.

14. A method for manufacturing a flexible liquid crystal display panel, comprising:
forming a first flexible substrate, comprising:
providing a first carrier; and
forming a first flexible base on the first carrier;
forming a second flexible substrate, comprising:
providing a second carrier;
forming a second flexible base on the second carrier; and
forming an active array on the second flexible base;
forming a liquid crystal layer between the first flexible substrate and the second flexible substrate; and
thinning the first flexible base and the second flexible base after the step of forming the liquid crystal layer between the first flexible substrate and the second flexible substrate.

15. The method according to claim 14, wherein the step of forming the second flexible substrate further comprises:
forming an insulating material layer on the active array;
patterning the insulating material layer to form a plurality of bumps thereon;
forming a reflective layer on the plurality of bumps; and
forming a color filter layer on the reflective layer.

16. The method according to claim 15, further comprising:
removing the first carrier and the second carrier.

17. The method according to claim 15, wherein the first flexible base is comprised of Polycarbonate (PC), Polyphenylene Sulfide (PES), polyethylene 2,6-naphthalate (PEN) or Polyimide (PI), and the second flexible base is comprised of metal.

18. The method according to claim 15, wherein the step of forming the first flexible substrate is under a temperature of about 20° C. to about 200° C., and the step of forming the second flexible substrate is under a temperature of about 20° C. to about 350° C.

19. A method for manufacturing a flexible panel, comprising:
forming a solid substrate, wherein the solid substrate comprises a solid base;
forming a flexible substrate, wherein the flexible substrate comprises a flexible base;
assembling the solid substrate and the flexible substrate to connect with each other; and
thinning the solid base after the step of assembling the solid substrate and the flexible substrate.

20. The method according to claim 19, wherein solid base is comprised of glass or quartz, and wherein the flexible base is comprised of Polycarbonate (PC), Polyphenylene Sulfide (PES), polyethylene 2,6-naphthalate (PEN) or Polyimide (PI).
